(19) United States
(12) Patent Application Publication
(10) Pub. No.: US 2009/0032855 A1
(43) Pub. Date: Feb. 5, 2009

(54) METHOD FOR FORMING A DEEP TRENCH IN AN SOI DEVICE BY REDUCING THE SHIELDING EFFECT OF THE ACTIVE LAYER DURING THE DEEP TRENCH ETCH PROCESS

(76) Inventors: Patrick Press, Dresden (DE); Sven Beyer, Dresden (DE)

Correspondence Address: WILLIAMS, MORGAN & AMERSON, 10333 RICHMOND, SUITE 1100, HOUSTON, TX, 77042, US

(21) Appl. No.: 12/037,325

(22) Filed: Feb. 26, 2008

(30) Foreign Application Priority Data
Jul. 31, 2007 (DE) 10 2007 035 832.8

(51) Int. Cl. H01L 29/94; H01L 21/76

(52) U.S. Cl. 257/301; 438/429; 257/E21.54; 257/E29.345

(57) ABSTRACT

By providing a conductive connection between the active semiconductor layer and the substrate material in an SOI device during the anisotropic etch process for forming a deep trench portion in the substrate material, the uniformity of the etch conditions may be increased, thereby enabling greater etch depth and enhanced controllability with respect to the shape of the deep trench portion.

### BACKGROUND OF THE INVENTION

1. Field of the Invention

The present disclosure generally relates to the field of fabricating integrated circuits, and, more particularly, to forming deep trenches in semiconductor devices including field effect transistors based on a silicon-on-insulator (SOI) architecture and capacitors formed on the basis of deep trenches extending through the buried insulating layer, such as capacitors for dynamic random access memories (DRAMs), vertical decoupling capacitors and the like.

2. Description of the Related Art

In modern integrated circuits, a very high number of individual circuit elements, such as field effect transistors in the form of CMOS, NMOS, PMOS elements, resistors, capacitors and the like are formed on a single chip area. Typically, feature sizes of these circuit elements are steadily decreasing with the introduction of every new circuit generation, to provide currently available integrated circuits with an improved degree of performance in terms of speed and/or power consumption. A reduction in size of transistors is an important aspect in steadily improving device performance of complex integrated circuits, such as CPUs. The reduction in size commonly brings about an increased switching speed, thereby enhancing signal processing performance while, however, increasing dynamic power consumption of the individual transistors. That is, due to the reduced switching time period, the transient currents upon switching a CMOS transistor element from logic low to logic high are significantly increased.

In addition to the large number of transistor elements, a plurality of passive circuit elements, such as capacitors, are typically formed in integrated circuits that are used for a plurality of purposes, such as for decoupling. Decoupling in integrated circuits is an important aspect for reducing the switching noise of the fast switching transistors, since the decoupling capacitor may provide energy at a specific point of the circuitry, for instance at the location of a fast switching transistor, and thus reduce voltage variations which may otherwise unduly affect the logic state represented by the transistor.

Another important aspect of providing capacitors in advanced semiconductor devices is the incorporation of memory devices including dynamic random access devices, which typically require a charge carrier storage element. For example, sophisticated CPUs and also many other advanced integrated circuits require extended memory functions wherein the charge carrier storage capability of the capacitors may have an influence on the overall performance of the corresponding SRAM portion. Consequently, the respective trenches for accommodating an appropriate capacitor dielectric and capacitor electrode materials may have to extend deeply into the semiconductor material to provide the desired high capacitance. For example, for advanced semiconductor devices including an embedded DRAM area, a depth up to 8 μm may be required with respect to achieving the required capacitance. The etch process for forming deep trenches, therefore, represent highly critical process steps during the formation of embedded DRAM areas, since the precise depth, the sidewall angles and the like may essentially influence the finally obtained performance of the respective capacitors. Consequently, sophisticated etch processes on the basis of appropriate plasma ambients have been established for silicon-based transistors with a bulk configuration, in which the active region of the transistor is electrically connected to the substrate material. During a corresponding anisotropic etch process, an appropriate plasma atmosphere is generated in which reactive ions are created and are accelerated towards the surface to be etched in order to obtain a high directionality for providing a moderately high physical component, which is substantially oriented perpendicular to the surface of interest. Furthermore, respective polymer materials may be added to the etch ambient of the respective anisotropic etch process in order to appropriately reduce a lateral etch component, while substantially not affecting the vertical progress of the corresponding etch front. Due to the highly complex conditions within the plasma etch ambient, which may even alter with the height level within the opening, highly stable process conditions are required to achieve a uniform process result. In particular, since a high degree of directionality has to be maintained within the etch opening during the ongoing etch process, the bias voltage applied between the plasma ambient and the substrate represents a critical process parameter, which may significantly affect the etch rate and also the degree of directionality, in particular if deep trenches up to 8 μm may have to be etched. Typically, the respective bias voltage may be established on the basis of a DC voltage source or on the basis of RF (radio frequency) bias generators, which may be controlled with high accuracy. However, the actually effective bias voltage at the substrate is substantially determined by the local conditions of the substrate to be etched, wherein, in particular, conductive areas of extended size may significantly reduce the effect of the external bias voltage sources when the corresponding areas may not be tied to a defined potential. This may be accomplished in a bulk configuration by connecting the substrate with the external bias voltage source, thereby also creating the same potential in the respective regions of the substrate material in which the deep trench is to be formed.

However, in SOI devices, the active semiconductor layer is electrically insulated from the substrate portion thereby resulting in significantly different etch conditions, as will be described in more detail with reference to FIGS. 1a-1c.

FIG. 1a schematically illustrates a cross-sectional view of a semiconductor device 100, in which at least a portion thereof is formed on the basis of an SOI configuration. Thus, the semiconductor device 100 comprises a substrate material 101 in the form of a silicon-based material above which is formed a buried insulating layer 102 that is typically comprised of silicon dioxide. A silicon layer 103, in and above which circuit elements have to be formed, such as transistors and the like, is formed on the buried insulating layer 102, wherein, in advanced semiconductor devices, a thickness of the silicon layer 103 is typically in the range of approximately 10-100 nm. Consequently, the thickness of the silicon layer 103 is not appropriate for providing a sufficient depth for vertical capacitors to be formed in the semiconductor device 100. Consequently, a respective deep trench capacitor is formed in the silicon layer 103, the buried insulating layer 102 and in the substrate material 101. For this purpose, the semiconductor device 100 may be prepared for a deep trench etch sequence at any appropriate manufacturing stage, for instance prior to or after the formation of other circuit elements, such as transistors, depending on the process and device requirements. To this end, a hard mask layer 105, which may be comprised of any appropriate material or a material composition, which may also include anti-reflective coating (ARC) materials, if required, and the like may be formed above the silicon layer 103, wherein an etch stop layer 104 may be provided, if required. For example, the hard mask layer 105 may be comprised of silicon nitride while the etch stop layer 104 may be comprised of silicon dioxide. Furthermore, a resist layer 106 may be formed on the hard mask layer 105 and may comprise a trench opening 106A that substantially corresponds to a trench to be formed in the silicon layer 103, the buried insulating layer 102 and the substrate material 101.

The semiconductor device 100 may be formed on the basis of well-established techniques, including the deposition or oxidation of the layer 104, the deposition of the hard mask layer 105 followed by advanced lithography techniques for depositing, exposing and developing the resist layer 106. Next, an appropriate anisotropic etch process may be performed on the basis of well-established recipes in order to transfer the opening 106A into the hard mask layer 105, which may then be used for the further processing so as to form the desired deep trench.

FIG. 1b schematically illustrates the semiconductor device 100 after the above-described process sequence wherein an opening 105A is formed in the hard mask layer 105, while the resist layer 106 may have been removed. Next, the etch stop layer 104 may be opened on the basis of appropriate dry or wet chemical etch recipes, thereby exposing the silicon layer 103.

FIG. 1c schematically illustrates the semiconductor device 100 in an advanced stage of an etch process 110 including a first sequence for etching through the silicon layer 103, followed by a step for etching through the buried insulating layer 102, which may possibly require a different etch chemistry, depending on the etch strategy. Thereafter, the etch process 110 may be continued on the basis of appropriately selected process parameters in order to form a deep trench portion in the substrate material 101. As previously explained, during the etch process 110, a plasma ambient is established, wherein an appropriate bias voltage has to be established on the basis of a corresponding bias voltage source 110A which may be connected to the substrate material 101, for instance by contacting the back side of the substrate material 101 on the basis of an appropriate substrate holder (not shown) and the like, as is well established in the art.

As previously explained, the buried insulating layer 102 may dielectrically isolate the semiconductor layer 103 and the material 101 so that the silicon layer 103 may represent a “floating” conductive area wherein charge carriers may accumulate due to the presence of ionized particles in the plasma ambient of the process 110, which may readily come into contact with the materials in the opening 101A. As a consequence, the silicon layer 103 may act as a floating capacitor electrode with the buried insulating layer 102 serving as a capacitor dielectric, thereby significantly influencing the overall potential established by the bias voltage source 110A. Thus, the external voltage may typically be reduced, thereby affecting the etch conditions in the opening 101A and also reducing the trench depth that may be achieved during the process 110 and also the shape of the trench, i.e., the angle of the sidewalls, may be affected thereby contributing to enhanced non-uniformity and a reduced predictability of the entire etch process 110. For example, using identical process parameters for otherwise identical devices, a trench depth of approximately 8 μm may be obtained for a bulk device, while the resulting etch depth in the SOI configuration, as shown for example in the semiconductor device 100, may result in an etch depth of approximately 4 μm. Since the effective capacitor depth, as well as the shape of the trench, have a significant influence on the finally obtained performance of the DRAM capacitor, device reliability as well as operating speed may be significantly deteriorated when forming a deep trench capacitor on the basis of an SOI configuration.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein contemplates new techniques and semiconductor devices in which capacitors may be provided in an SOI configuration with increased reliability and performance by enhancing a corresponding manufacturing sequence for etching the deep trench through the active semiconductor layer, the buried insulating layer and into the substrate material of the SOI device. For this purpose, the active semiconductor layer may be tied to a defined potential during the anisotropic etch process, that is, during the part of the etch process in which a deep trench portion is formed in the substrate material, thereby providing well-defined etch conditions with respect to a bias voltage applied for obtaining the desired high degree of directionality during the etch process. In illustrative aspects disclosed herein, the active semiconductor layer may be tied to the substrate potential by establishing a conductive connection, thereby obtaining similar conditions as in the case of bulk devices, enabling an efficient etch process resulting in similar trench depths and shapes as in bulk devices.

One illustrative method disclosed herein comprises forming a trench in a semiconductor layer and a buried insulating layer, wherein the trench extends into a substrate material of an SOI semiconductor device. Furthermore, the method comprises forming a conductive material at least on sidewalls of a trench and subsequently performing an etch process to deepen the trench in the substrate material according to a specified target depth to provide a deep trench.

Another illustrative method disclosed herein contemplates the formation of a deep trench in an SOI device, wherein the method comprises performing a first etch sequence to etch through a semiconductor layer and a buried insulating layer to form a first trench portion extending into a substrate material of the SOI device. The method further comprises treating at least sidewall portions of the first trench portion so as to form a conductive connection between the semiconductor layer and the substrate material. Additionally, the method comprises performing a second etch sequence to form a second trench portion of the deep trench within the substrate material.

An illustrative semiconductor device disclosed herein comprises a semiconductor material and a buried insulating layer formed on the semiconductor material. Moreover, a semiconductor layer is formed on the buried insulating layer and a deep trench capacitor is provided. The deep trench capacitor extends from the semiconductor layer into the semiconductor material and comprises an upper capacitor portion and a lower capacitor portion. A boundary between the upper capacitor portion and the lower capacitor portion is defined by a step-like change of trench widths.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate cross-sectional views of an SOI semiconductor device during various manufacturing stages in forming a deep trench in a certain device region according to conventional strategies; and

FIGS. 2a-2g schematically illustrate cross-sectional views of an SOI semiconductor device during various manufacturing stages in forming a deep trench capacitor extending from an active semiconductor layer into the substrate material of the device using an enhanced manufacturing strategy for stabilizing the conditions during an anisotropic etch process according to illustrative embodiments.

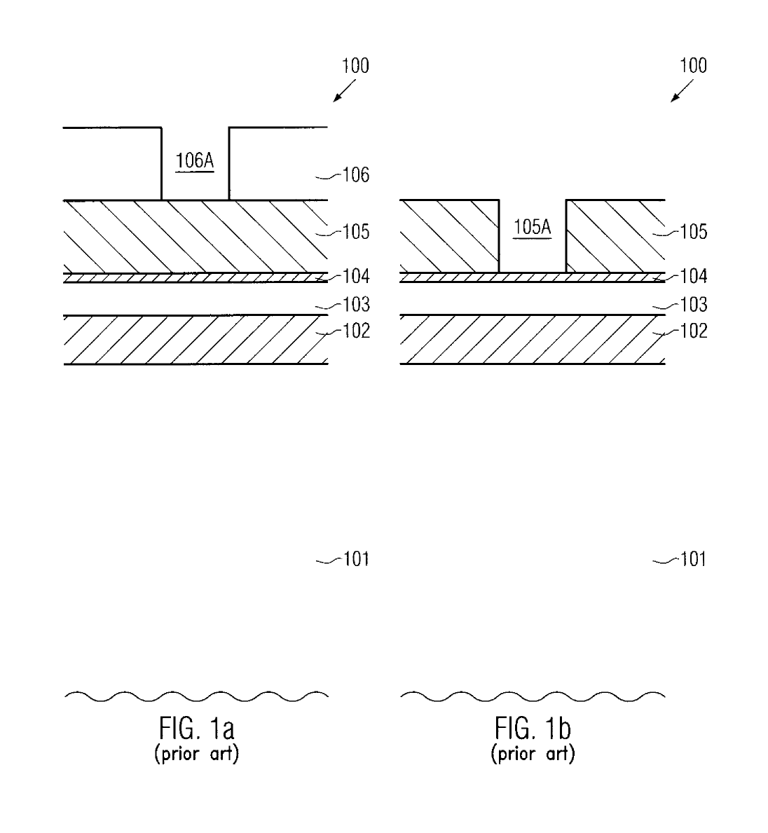

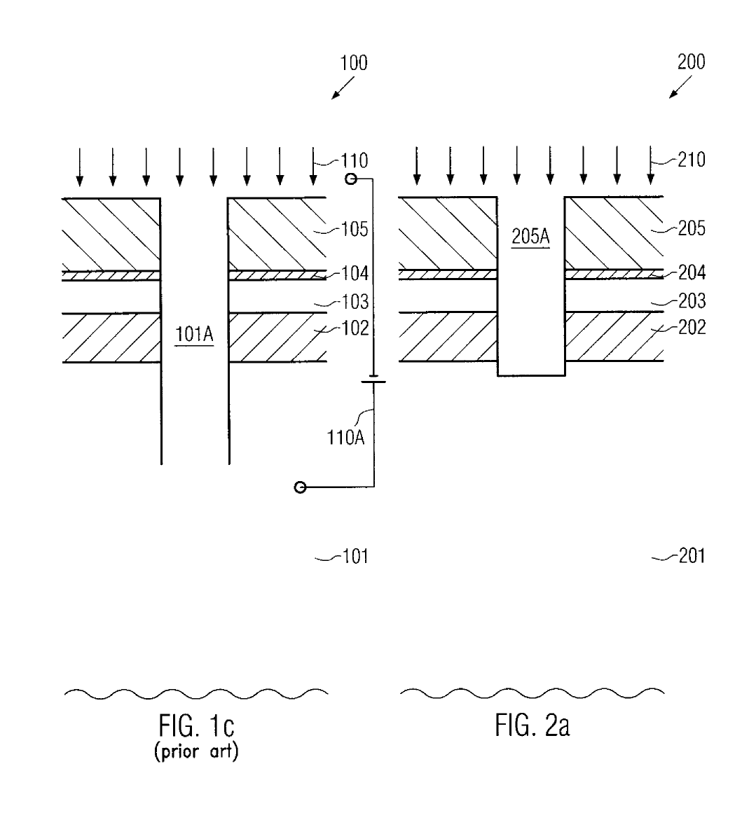

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The subject matter disclosed herein relates to an enhanced technique for forming semiconductor devices on the basis of an SOI architecture wherein deep trenches may be formed through the semiconductor layer, the buried insulating layer and a portion of the substrate material on the basis of process conditions during a plasma-assisted etch process having enhanced stability compared to conventional strategies. For this purpose, the dielectric isolation between the active semiconductor layer and the substrate material is temporarily “disabled” in order to provide a predictable and stable potential during the complex anisotropic etch process for forming the deep trench portion in the substrate material of the SOI device. To this end, a conductive connection between the semiconductor layer and the substrate material may be temporarily established within an upper portion of the trench prior to actually forming the deep trench portion in the substrate material, thereby providing a high degree of compatibility with existing process recipes, while nevertheless accomplishing a significantly enhanced etch depth that is comparable to process results obtained on the basis of bulk architectures. In some illustrative embodiments, the electrical connection may be established by depositing a conductive material at least on sidewall portions of an upper portion of the trench, while, in other cases, other surface treatments, such as plasma-based incorporation of metallic components and the like may be used so as to obtain the desired temporary conductive connection.

It should be appreciated that the subject matter disclosed herein is highly advantageous in the context of SOI semiconductor devices requiring an embedded DRAM area, such as sophisticated CPUs, highly complex ASICs and the like, since in this case non-uniformities in the embedded DRAM area caused by etch fluctuations may directly translate into device reliability and operating speed, as previously explained. In other cases, the principles disclosed herein may also be advantageously applied to the formation of vertical decoupling capacitors, since, also in this aspect, enhanced etch stability may allow increased capacitor depths thereby providing increased capacitance of respective decoupling capacitors, resulting in an overall performance increase of advanced semiconductor devices, such as CPUs, logic circuits and the like, in which a moderately high degree of switching noise is to be compensated for.

Thus, unless otherwise explicitly stated in the specification and/or the appended claims, the present invention should not be considered as being restricted to DRAM deep trench capacitors but may be applied to any situation in which a deep trench is to be formed in advanced SOI devices.

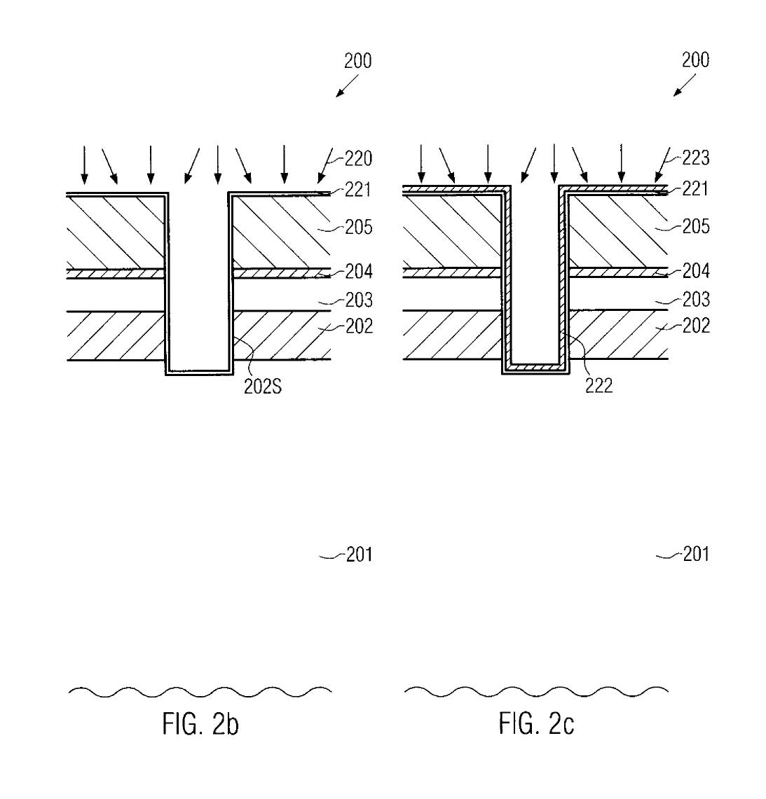

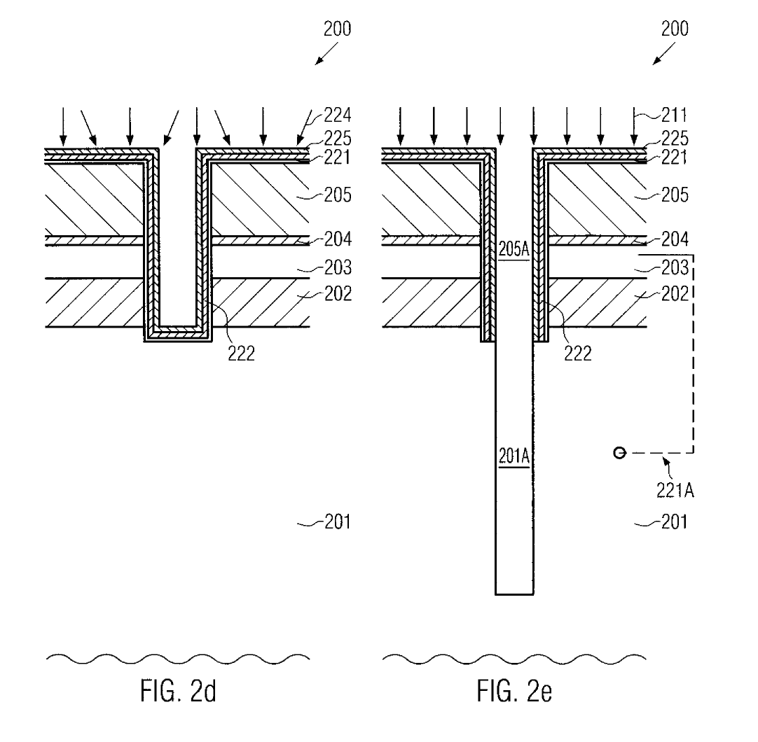

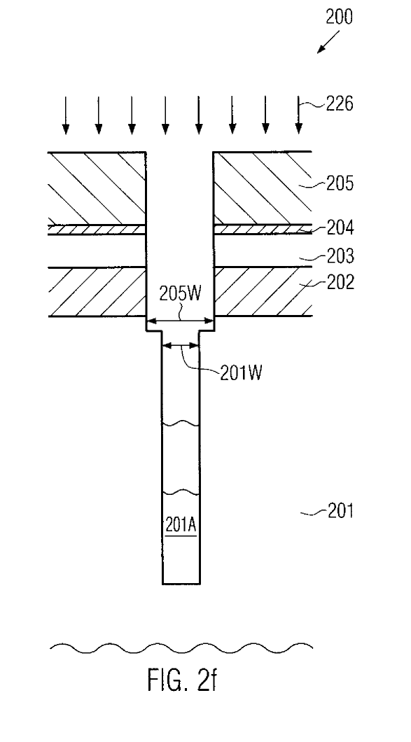

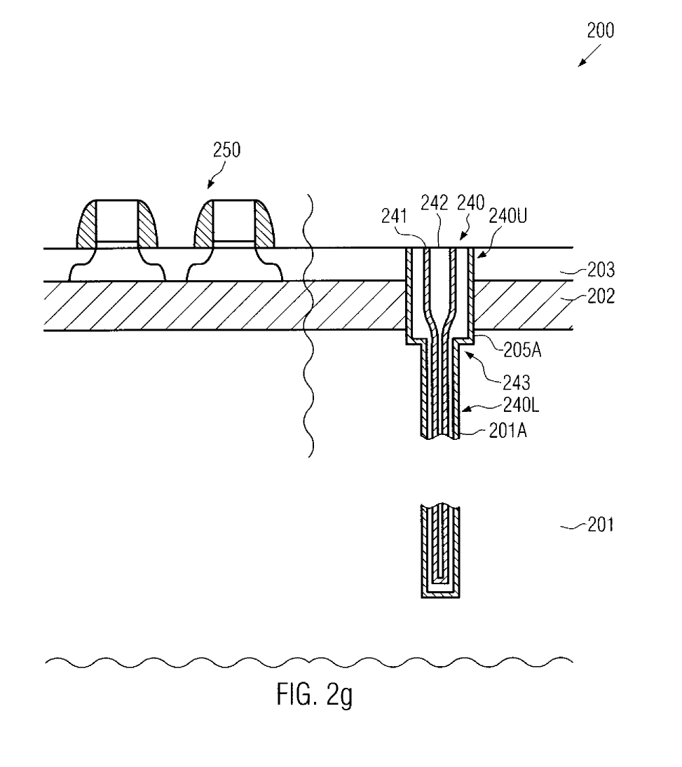

FIG. 2a schematically illustrates a cross-sectional view of a semiconductor device 200 which may comprise at least a portion having a silicon-on-insulator (SOI) configuration. That is, the semiconductor device 200 may also comprise, in some illustrative embodiments, a bulk configuration at certain device areas in which an SOI configuration may be considered inappropriate. For instance, the semiconductor device 200 may represent an integrated circuit having a complex logic block, a static RAM area and a dynamic RAM area. In this case, an appropriate configuration may be selected for the various device areas, depending on the device requirements. In the following, it may be assumed that the portion of the device 200 shown and described represents an SOI configuration in which a deep trench is to be formed, which may be used for fabricating a capacitor. Thus, the semiconductor device 200 may comprise a substrate 201 which may include, at least in an upper portion thereof, a semiconductor material such as silicon, silicon germanium, germanium, semiconductor compounds on the basis of II-VI, III-V compounds, and the like. For complex integrated circuits, typically the substrate material 201 may comprise a silicon-based material since presently and in the foreseeable future highly complex semiconductor devices may be fabricated on the basis of silicon due to superior availability of silicon and the sophistication of mass product techniques obtained over the past decades. A buried insulating layer 202, for instance comprised of silicon dioxide, silicon nitride, silicon oxynitride or any other appropriate dielectric material, is formed above the substrate material 201, thereby dielectrically isolating an active semiconductor layer 203 from the substrate material 201 and providing the advantages of a typical SOI architecture with respect to operating speed of respective transistor elements, immunity against latch-up, enhanced immunity against energetic radiation and the like. The semiconductor layer 203 may comprise silicon, possibly in combination with other components, such as germanium, carbon and the like, so as to adapt the characteristics of the layer with respect to the desired device performance. In other cases, any other appropriate semiconductor material may be used for forming the semiconductor layer 203. As previously explained, in advanced semiconductor devices formed on the basis of silicon material, the semiconductor layer 203 may have a thickness of several nanometers to several tenths of nanometers, depending on the device architecture and the like.

Furthermore, in this manufacturing stage, the semiconductor device 200 may comprise a hard mask 205 including an opening 205A, which may substantially correspond to a trench to be formed in the substrate material 201 in a later manufacturing stage. The hard mask 205 may be comprised of any appropriate material or material compositions, such as silicon dioxide, silicon nitride, silicon oxynitride, silicon carbide and the like, wherein the material composition and the thickness may be appropriately selected so as to obtain the desired etch behavior, the optical response during a photolithography process and the like. For this purpose, well-established material compositions may be used. Moreover, an etch stop layer 204 may be provided between the semiconductor layer 203 and the hard mask layer 205. In some illustrative embodiments, the etch stop layer 204 may be comprised of silicon dioxide if the hard mask layer 205 may comprise, at least in a portion immediately formed above the etch stop layer 204, silicon nitride or any other material having a moderately high etch selectivity with respect to silicon dioxide. In other illustrative embodiments, the etch stop layer 204 may be formed on the basis of other materials, such as silicon carbide, silicon nitride and the like, as long as a desired high etch selectivity is established between the layers 205 and 204.

The semiconductor device 200 may be formed on the basis of well-established techniques, as are also described previously with respect to the semiconductor device 100. It should further be appreciated that the manufacturing stage shown in FIG. 2a may correspond to any appropriate point in the overall manufacturing process that is compatible with the manufacturing of other circuit elements, such as transistors and the like. For instance, in some illustrative embodiments, the structure shown in FIG. 2a may represent a device portion formed after respective manufacturing processes for forming transistor elements in other device areas (not shown). In other cases, the portion of the device 200 as shown may be formed prior to or during a manufacturing sequence for forming transistor devices and the like. Thus, after providing the substrate 201, which may have formed thereon the buried insulating layer 202 and the semiconductor layer 203, or after forming the SOI configuration defined by the substrate material 201, the buried insulating layer 202 and the semiconductor layer 203 by other advanced techniques, the etch stop layer 204 and the hard mask layer 205 may be formed on the basis of well-established techniques wherein, as previously mentioned, other circuit elements may already have been manufactured or may be formed after or during a corresponding process sequence.

Furthermore, the device 200 is subjected to a first etch sequence 210 for forming the opening 205A and, based on this opening, etching through the etch stop layer 204, the semiconductor layer 203 and the buried insulating layer 202 so as to obtain the opening 205A in such a way that it extends into the substrate material 201. As previously discussed, different plasma-assisted etch ambients may be required for etching through the mask layer 205, the semiconductor layer 203 and the buried insulating layer 202, wherein typically the anisotropic nature of the process 210 is less critical since the total thickness of the opening 205A may be significantly less compared to a deep trench portion still to be formed in the substrate material 201. As previously explained, a depth of several micrometers, for instance approximately 8 μm, may be required, whereas a depth of the opening 205A may be less than 1 μm.

FIG. 2b schematically illustrates the semiconductor device 200 during a treatment 220 that is designed to modify the conductivity of at least a portion of sidewalls of the trench 205A. That is, at least sidewall portions 202S are modified so as to obtain a certain degree of conductivity, thereby establishing an electrical connection between the semiconductor layer 203 and the substrate material 201. Consequently, the layer 203 and the substrate material 201 may be electrically connected and may therefore be substantially at the same potential during a subsequent anisotropic etch process. In one illustrative embodiment, the treatment 220 may comprise a deposition process for forming a conductive material on exposed sidewall portions of the trench 205A. In this case, the deposition process 220 may be designed to provide a conformal layer 221 comprised of a material that exhibits a certain degree of conductivity so as to allow a charge carrier flow between the layers 203 and 201. It should be appreciated that a moderately low conductivity may still be sufficient for providing the desired electrical connections between the layer 203 and the substrate material 201. For example, in some illustrative embodiments, the intrinsic conductivity of a semiconductive material may be sufficient for providing the desired drive current capability. In one illustrative embodiment, the layer 221 may be comprised of silicon, which may be doped to a certain degree, if the intrinsic conductivity of polycrystalline silicon is considered as too low. In other cases, a substantially intrinsic polycrystalline material may be deposited during the process 220. For this purpose, any appropriate deposition techniques, such as chemical vapor deposition (CVD) and the like, may be used, as are well established in the art. A thickness of the conductive layer 221 may be selected on the basis of the material characteristics and the degree of conductivity required. For instance, the layer 221, when provided in the form of a polysilicon layer, may have a thickness of 3-10 nm or even more, depending on the process strategy. In other illustrative embodiments, the process 220, when performed as a deposition process, may be designed so as to form a conductive layer including a metallic component, such as titanium, tantalum, tungsten and the like, or other refractory metals may be provided, such as cobalt, nickel and the like. Furthermore, appropriate conductive compositions including these metals may be used, wherein well-established deposition techniques, such as sputter deposition, CVD, atomic layer deposition (ALD), which may be considered as a self-limiting CVD technique, and the like, may be used. In some illustrative embodiments, the conductive layer 221 may be provided in the form of a conductive material composition having a high etch selectivity with respect to an etch ambient of a plasma-assisted etch process to be performed at a later stage for forming the deep trench portion. In this case, a respective material removal during the subsequent anisotropic etch process may not completely remove the layer 221, especially at the portion 202S, thereby maintaining the conductive connection between the layer 203 and the substrate material 201 throughout the entire etch process, without requiring additional measures for protecting the layer 221.

In other illustrative embodiments, the treatment 220 may comprise a plasma-based surface treatment so as to incorporate a metallic component in surface areas of the exposed sidewall portions of the trench portion 205A, thereby imparting a certain degree of conductivity to the per se dielectric material of the buried insulating layer 202. For example, a plasma-based treatment using an appropriate precursor material, such as a tantalum-containing precursor and the like, may be applied, thereby providing a conductive surface at the portion 202S resulting in a conductive connection between the layer 203 and the material 201.

FIG. 2c schematically illustrates the semiconductor device 200 in a further advanced manufacturing stage according to further illustrative embodiments. In this case, a first protection layer 222 may be formed on the basis of a process 223 which, in some illustrative embodiments, may represent a deposition process to deposit the layer 222 having the desired characteristics for protecting the layer 221. For example, the layer 222 may be provided in the form of a material having a high etch selectivity with respect to the subsequent anisotropic etch process, thereby substantially preventing or at least significantly reducing a material removal of the conductive layer 221 so as to reliably maintain the electric connection between the layer 203 and the substrate material 201 during the entire etch sequence. In other illustrative embodiments, the layer 222 may represent an appropriate liner material providing for etch stop capabilities for a further protective material still to be formed on the layer 222. Providing the layer 222 in the form of an etch stop material for controlling the removal of a further protection layer still to be formed may be advantageous with respect to a highly controllable removal of a protective material and also of the layer 221, since then a corresponding removal process designed to remove the layer 221 may encounter highly uniform process conditions, irrespective of any etch damage created in a respective protective material during the anisotropic etch process for forming the deep trench portion.

In one illustrative embodiment, the layer 222 may be provided in the form of a dielectric material, such as silicon dioxide, silicon nitride and the like, which provides the desired etch selectivity, as previously explained. For instance, the layer 222 may be deposited in the form of silicon dioxide on the basis of well-established CVD techniques, when the actual protective material may be provided in the form of silicon nitride, silicon oxynitride and the like so as to obtain a high etch selectivity on the basis of well-established recipes. In still other illustrative embodiments, the process 223 may comprise a surface treatment or any other treatments, such as oxidation, nitridation and the like, in order to appropriately modify the characteristics of a surface portion of the previously formed conductive layer 221. For example, the layer 221 may be provided in the form of polysilicon, which may then be partially oxidized on the basis of well-established process parameters, thereby providing the layer 222. Since corresponding oxidation rates are well known in the art, the initial layer thickness of the layer 221 may be appropriately selected so as to maintain the required conductivity, in particular at the sidewall portion 202S, while nevertheless providing a desired thickness of the layer 222.

In other cases, the layer 222 may be provided in the form of a conductive material, wherein the provision of two different conductive layers 221 and 222 may provide enhanced process reliability, while also resulting in an increased controllability during a process sequence for removing the layer 221 and 222 in a later manufacturing stage.

FIG. 2d schematically illustrates the semiconductor device 220 during a process 224 configured to form a second protection layer 225, which may exhibit a high resistance against an etch ambient for the subsequent anisotropic etch process, as previously explained. In one illustrative embodiment, the second protection layer 225 may be comprised of silicon nitride, silicon carbide, nitrogen-enriched silicon carbide and the like. In one illustrative embodiment, the layer stack comprised of the layer 221, 222 may be a polysilicon/silicon dioxide/silicon nitride layer stack, which may be formed on the basis of well-established process techniques and which exhibits a desired mutual etch selectivity with respect to well-established etch chemistries, thereby enabling an efficient and highly controllable removal of the layers 221, 222 and 225 in a later manufacturing stage. In other cases, other material compositions may be used, such as a metal-containing layer for the layer 221 in addition to one or both of the layers 222 and 225, which may then have any appropriate material composition so as to provide an efficient removal process, as explained above. In still other cases, a single conductive layer may be sufficient as far as it has sufficient etch selectivity so as to ensure that the electrical connection between the layer 203 and the material 201 is maintained until the anisotropic etch process for forming the deep trench portion is completed.

FIG. 2e schematically illustrates the semiconductor device 200 during a second etch sequence 211 designed to form a deep trench portion 210A within the substrate material 201. As previously explained, the etch sequence 211 may comprise a highly anisotropic etch process on the basis of a plasma ambient, in which a corresponding bias voltage may be applied, for instance on the basis of a DC source or an RF source, as previously explained, in order to obtain the desired high degree of directionality for the physical etch component of the process 211. Due to the electrical connection between the semiconductor layer 203 and the substrate material 201, which is schematically indicated as connection 221A, the potential of the layer 203 may be maintained at a well-defined value thereby significantly stabilizing the etch conditions and in particular not unduly weakening the electric field required for inducing the desired particle bombardment. During the etch sequence 211, the upper trench portion 205A has formed therein at least the conductive layer 221, which may now act as a “sidewall spacer” that substantially determines the width of the deep trench portion 210A, in combination with the respective etch process parameters, wherein a corresponding reduction in width may be taken into consideration by appropriately selecting the width of the opening 205A of the hard mask layer 205. That is, if a specific width of the lower portion 201A is desired, wherein it should be appreciated that a certain degree of tapering may be involved during the process 211, the target thicknesses of the layers 221 and 222 and 225, if provided, may be adjusted so as to establish the required target width of the opening 205A. Consequently, during the anisotropic etch process 211, similar etch conditions may be obtained as are also encountered in a semiconductor device having a bulk configuration, i.e., when the buried insulating layer 202 is missing, thereby providing the possibility of using well-established etch techniques developed for bulk semiconductor devices. In some embodiments, the layer thickness of the layers 221, 222 and 225 may be used to adjust the width of the deep trench portion to a desired target thickness without restrictions with respect to photolithography constraints. It should be appreciated that, during the etch process 211, a bottom portion of the layers 221, 222 and 225 may have to be removed on the basis of any appropriate recipe to expose the substrate material 201. Hence, in this case, a first etch step may be incorporated into the process 211 in order to appropriately expose the material 201. Furthermore, during a corresponding etch process, horizontal portions may also be removed or at least be significantly reduced in thickness, which, however, may not negatively affect the overall process, since the actual masking effect is provided by the mask layer 205. During the process 211, a certain degree of material removal may also occur for the layers 225, 222 and 221, which may, however, not result in a complete removal of these materials, especially at the upper portion 205A, since here the directionality of the particle bombardment is typically more pronounced compared to the deep trench portion 201A. Thus, a substantially vertical etch direction may prevail in the upper trench portion 205A. Consequently, even if the layer 221 may be exposed after the removal of horizontal portions of the layers 225 and 222, the corresponding etch rate would be significantly lower compared to the actual etch rate of the substrate material 201, thereby substantially ensuring that the electrical connection 221A may be maintained until the desired target depth for the deep trench portion 201A is reached.

FIG. 2f schematically illustrates the semiconductor device 200 in a further advanced manufacturing stage, in which an etch process 226 may be performed to remove material residues of the layer 221 and of the layers 222 and 225, if provided. For this purpose, well-established isotropic wet etch and/or dry etch techniques may be used, wherein, as previously explained, a highly controlled removal process may be obtained if an appropriate stack of layers has been used during the previous etch process 211. For example, if a polysilicon/silicon dioxide/silicon nitride layer stack has been used for the layers 221, 222 and 225, the etch process 226 may comprise the removal of the silicon nitride layer 225 on the basis of hot phosphoric acid, and diluted hydrofluoric acid for the layers 225, 222, while the polysilicon material may be removed on the basis of appropriate well-established isotropic plasma-assisted etch processes, thereby reliably exposing the sidewall portions 202S. Since the corresponding removal processes may be performed in a step-wise manner with a high degree of process control at each step, the final removal of the polysilicon material may be accomplished on the basis of a highly controllable isotropic dry etch process using well-established recipes without undue material removal of other silicon-based areas, such as the semiconductor layer 203 and the substrate material 201, if provided in the form of a silicon-based material. It should be appreciated that other etch chemistries may be used during the process 226, depending on the material composition of the layer or layers used for establishing the conductive connection 221A. Consequently, after removal of the material residues of the conductive connection 221A, the upper trench portion 205A may comprise a width 205W at an area that connects to the deep trench portion 201A, which in turn may have a width 201W that is less than the width 205W due to the fact that the layers 221, 222 and 225 may have been served as sidewalls spacers.

FIG. 2g schematically illustrates the semiconductor device 200 in a further advanced manufacturing stage, wherein a deep trench capacitor 240 may comprise an upper capacitor portion 240U and a lower capacitor portion 240L, which are formed on the basis of the trench portions 205A and 201A. Furthermore, circuit elements 250, for instance in the form of field effect transistors, may be provided wherein at least some of the circuit elements 250 may be electrically connected with the deep trench capacitor 240 on the basis of any appropriate interconnect structure (not shown). The deep trench capacitor 240 may comprise a capacitor dielectric material 241 in combination with an electrode material 242, wherein it should be appreciated that the capacitor 240 may have any appropriate configuration depending on the device and process requirements. For instance, doped polysilicon material may be used as electrode material 242, while silicon dioxide or any other appropriate dielectric materials may be used as the capacitor dielectric 241. As previously explained with reference to FIG. 2f, the deep trench capacitor 240 may have different widths additionally to any tapering that may be caused during the anisotropic etch process 211, due to the fact that the trench portions 205A and 201A may have different widths at the corresponding transition area due to the masking effect of the layers 221, 222 and 225. Consequently, a boundary between the upper portion 240U and the lower portion 240L may be defined by an area 243 and the width of the capacitor 240 may undergo a substantially step-like change due to the difference in widths of the values 205W and 201W. In this respect, it should be appreciated that a “substantially” step-like change in trench width is to be understood such that a change in width of at least 20 nm occurs over a trench depth of less than 100 nm. That is, the area 243 may be understood as a transition area between the upper portion 240U and the lower portion 240L having a vertical extension of approximately 100 nm and less, in which the width changes from 205W to 201W, wherein this difference is substantially determined by the “width” of the respective spacers formed by the layers 221, 222 and 225 during the deep trench etch process. Thus, the difference in width of the values 205W and 201W may range from approximately 20-100 nm.

It should be appreciated that a corresponding change in width may not negatively affect the performance of the capacitor 240 which, however, may have a significantly improved electrical performance compared to conventional SOI devices having formed therein deep trench capacitors that are produced on the basis of the same etch conditions during the process 211, due to the fact that a significantly increased etch depth may be obtained due to the electrical connection 221A, while also obtaining a desired depth of the respective deep trench portion 201A. Consequently, the performance of the circuit elements 250 electrically connected to the deep trench capacitor 240 may be significantly enhanced or the packing density of the device 200 may be increased compared to conventional SOI devices, since, in these devices, an increased lateral size of respective deep trench capacitors may be required to compensate for the loss of depth compared to bulk devices.

As a result, the subject matter disclosed herein provides techniques and semiconductor devices on the basis of an SOI architecture in which deep trench capacitors may be formed with increased uniformity and efficiency by ensuring that the active semiconductor layer may be maintained at a well-defined potential during the anisotropic etch process for forming the deep trench portion. This may be accomplished by depositing a conductive material prior to the respective etch process and/or by appropriately treating the surface of sidewall portions of the upper trench portion while, in some illustrative embodiments, additional protective material may be provided to reliably maintain the electrical connection during the entire anisotropic etch process. The conductive material may be reliably removed on the basis of well-established process recipes, thereby substantially not unduly affecting the further processing during forming the deep trench capacitor. In this case, a well-defined difference in width between an upper portion and a lower portion may be obtained, without requiring any other manipulations in the trench configuration which may, for instance, be used in some conventional approaches when isotropically etching the silicon material of the active semiconductor layer prior to performing the anisotropic etch process for forming the deep trench portion in an attempt to reduce the effect of the floating semiconductor layer 203. Consequently, the subject matter disclosed herein provides a substantially uniform thickness of the upper trench portion, thereby enhancing the fill behavior of subsequent processes for forming the deep trench capacitor. Furthermore, the techniques and devices disclosed herein may be advantageously applied to any type of deep trench capacitor to be formed in an SOI device, such as vertical decoupling capacitors, dynamic RAM areas and the like.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench in a semiconductor layer and a buried insulating layer, said trench extending into a substrate material of an SOI semiconductor device;
forming a conductive material layer at least on sidewalls of said trench; and
performing an etch process so as to deepen said trench in said substrate material according to a specified target depth to provide a deep trench.

2. The method of claim 1, further comprising forming a protection layer on said conductive material layer prior to performing said etch process.

3. The method of claim 1, wherein forming said conductive material layer comprises depositing a conductive material.

4. The method of claim 3, wherein said conductive material comprises silicon.

5. The method of claim 3, wherein said conductive material comprises a metal species.

6. The method of claim 2, wherein forming said protection layer comprises forming at least a first layer and a second layer, said first and second layers having a different material composition.

7. The method of claim 2, wherein said protection layer comprises silicon dioxide.

8. The method of claim 2, wherein said protection layer comprises silicon nitride.

9. The method of claim 1, further comprising removing said conductive material layer after performing said etch process.

10. The method of claim 1, further comprising forming a capacitor in said deep trench.

11. The method of claim 10, wherein said capacitor represents a capacitor of a dynamic random access memory area of said semiconductor device.

12. The method of claim 10, wherein said capacitor represents a decoupling capacitor.

13. A method for forming a deep trench in an SOI device, the method comprising:
performing a first etch sequence to etch through a semiconductor layer and a buried insulating layer to form a first trench portion extending into a substrate material of said SOI device;
treating at least sidewall portions of said first trench portion so as to form a conductive connection between said semiconductor layer and said substrate material; and
performing a second etch sequence to form a second trench portion of said deep trench in said substrate material.

14. The method of claim 13, wherein treating said sidewall portions of said first trench portion comprises incorporating a conductive species into surface areas of said sidewall portions.

15. The method of claim 14, wherein incorporating said conductive species comprises performing a plasma treatment on the basis of a metal-containing ambient.

16. The method of claim 13, wherein treating said sidewall portions comprises depositing a conductive material.

17. The method of claim 13, further comprising forming a protection layer at least on said sidewall portions after forming said conductive connection.

18. The method of claim 13, further comprising treating at least sidewall portions so as to remove said conductive connection after performing said second etch sequence.

19. A semiconductor device, comprising:
a semiconductor material;
a buried insulating layer formed on said semiconductor material;
a semiconductor layer formed on said buried insulating layer; and
a deep trench capacitor extending from said semiconductor layer into said semiconductor material, said deep trench capacitor comprising an upper capacitor portion and a lower capacitor portion, wherein a boundary between said upper and lower capacitor portions is defined by a substantially step-like change of trench width.

20. The semiconductor device of claim 19, wherein said step-like change occurs over a depth of approximately 100 nm or less.
